(19) United States
(12) Patent Application Publication
(10) Pub. No.: US 2014/0127864 A1
(43) Pub. Date: May 8, 2014

(54) METHOD OF FABRICATING A SEMICONDUCTOR PACKAGE

(71) Applicant: SILICONWARE PRECISION INDUSTRIES CO., LTD., Taichung (TW)

(72) Inventors: Kuan-Wei Chuang, Taichung Hsien (TW); Chun-Tang Lin, Taichung Hsien (TW); Yi-Che Lai, Taichung Hsien (TW)

(73) Assignee: SILICONWARE PRECISION INDUSTRIES CO., LTD., Taichung (TW)

(21) Appl. No.: 13/730,051

(22) Filed: Dec. 28, 2012

(30) Foreign Application Priority Data
Nov. 8, 2012 (TW) 101141515

(51) Int. Cl. H01L 21/58

(52) U.S. Cl. CPC H01L 21/58
USPC 438/123

(57) ABSTRACT

A method of fabricating a semiconductor package is provided, including providing an interposer having a plurality of conductive elements, disposing the interposer on a carrier having a plurality of recessed portions for the conductive elements to be received therein such that the interposer is coupled to the carrier, attaching the semiconductor element to the interposer, and removing the carrier. Coupling the interposer to the carrier prevents the conductive elements from displacement under pressure. Therefore, the conductive elements will not be in poor or no electrical contact with the interposer.

### BACKGROUND OF THE INVENTION

1. Field of the Invention

This invention relates to methods of fabricating a semiconductor package, and, more particularly, to a method of fabricating a flip-chip semiconductor package.

2. Description of Related Art

In a flip-chip package fabricating process, as the integrity of integrated circuit increases, thermal stress and warpage generated due to the mismatch of coefficients of thermal expansion (CTE) of a semiconductor chip and a packaging substrate are becoming severe. As a result, the reliability between the semiconductor chip and the packaging substrate is reduced, and a reliability test fails. In order to solve the problem, a three-dimensional chip stacking technique that employs a semiconductor substrate as an intermediate structure is brought to the market. According to the technique, a silicon interposer is installed between a packaging substrate and a semiconductor chip. Since the silicon interposer and the semiconductor chip are made of similar materials, the mismatch problem of CTEs of the packaging substrate and the semiconductor chip is solved.

In a general three-dimensional chip stacking technique, a silicon interposer is coupled to a packaging substrate via a plurality of conductive bumps, an underfill is formed to encapsulate the conductive bumps, a baking process is performed, and a semiconductor chip is disposed on the silicon interposer. However, since the silicon interposer and the packaging substrate have different CTEs, warpage is likely generated during the baking process. As a result, the conductive bumps installed between the silicon interposer and the packaging substrate are easily broken, and an electronic product having the conductive bumps thus has poor reliability.

To solve the problem, a method of fabricating another semiconductor package 1 is brought to the market, as shown in FIGS. 1A to 1E.

As shown in FIGS. 1A and 1B, a silicon interposer 10 having a first surface 10a and a second surface 10b opposite to the first surface 10a and a silicon carrier 12 having an adhesive layer 120 are provided. The silicon interposer 10 has a plurality of through silicon vias (TSV) 100 that communicate the first surface 10a with the second surface 10b. A plurality of solder balls 11 are disposed on the first surface 10a of the silicon interposer 10. A redistribution layer (RDL) 102 is formed on the second surface 10b of the silicon interposer 10 and electrically connected to the through silicon vias 100.

Then, the first surface 10a of the silicon interposer 10 is pressed to the carrier 12, and the solder balls 11 are pressed into the adhesive layer 120. A baking process is then performed. Since the carrier 12 and the silicon interposer 10 have similar CTEs and are rigid, warpage will not occur during the baking process. As a result, the solder balls 11 will not be broken.

As shown in FIG. 1C, a semiconductor chip 13 is coupled to the second surface 10b of the silicon interposer 10 via a plurality of conductive bumps 130 and electrically connected to the redistribution layer 102, and an underfill 131 is then formed between the semiconductor chip 13 and the redistribution layer 102 to encapsulate the conductive bumps 130.

As shown in FIGS. 1D and 1E, the carrier 12 and the adhesive layer 120 are removed to form a plurality of semiconductor structures 1′. The semiconductor structures 1′ are coupled to a packaging substrate 14 via the solder balls 11, and an underfill 15 is formed between the semiconductor structure 1′ and the packaging substrate 14 to encapsulate the solder balls 11. The semiconductor package 1 is thus formed.

In the method of fabricating the semiconductor package 1 according to the prior art, the adhesive layer 120 has to have a thickness w great enough (as shown in FIG. 1A, greater than 100 um) for the solder balls 11 to be pressed thereinto. Accordingly, the thickness w of the adhesive layer 120, when being formed, does not have a consistent distribution. In other words, the thickness w of the adhesive layer 120 has a poor distribution. As a result, when the first surface 10a of the silicon interposer 10 is pressed to the adhesive layer 10 and the silicon interposer 10 is thus parallel to the carrier 12 (as shown in FIG. 1B), the solder balls 11 pressed into the adhesive layer 120, if being under pressure, will make displacement. Accordingly, the solder balls 11 are in poor or even no electrical contact with the through silicon vias 100, and the reliability of the electronic product is reduced.

Therefore, how to solve the problems of the prior art is becoming an urgent issue in the art.

### SUMMARY OF THE INVENTION

In view of the problems of the prior art, the present invention provides a method of fabricating a semiconductor package, comprising: providing at least an interposer having a first surface, a second opposite to the first surface, and a plurality of conductive elements disposed on the first surface; disposing the interposer on a carrier, the carrier having a plurality of recessed portions for the conductive elements to be received therein such that the interposer is coupled to the carrier; attaching the semiconductor element to the second surface of the interposer; and removing the carrier.

In an embodiment, an interposer substrate is provided first, and the interposer substrate is cut into a plurality of interposers, allowing the at least an interposer to be disposed on the carrier.

In an embodiment, a singulation process is performed after the carrier is removed when the interposer substrate composed of a plurality of the interposers is employed.

In an embodiment, a packaging substrate is attached to the conductive elements after the carrier is removed.

In an embodiment, the interposer further has a release film formed on the first surface of the interposer and the conductive elements and attached to the carrier and the recessed portions, and the release film is removed after the carrier is removed.

In an embodiment, the recessed portions are formed by etching the carrier. For example, the carrier has an insulation layer, and the recessed portions are formed by etching the insulation layer.

In an embodiment, the interposer is a silicon-containing substrate, and has a plurality of conductive vias that communicate the first surface with the second surface and a redistribution layer electrically connected to the conductive vias and the semiconductor element.

In an embodiment, the recessed portions have a depth greater than a height of the conductive elements.

In a method of fabricating a semiconductor package according to the present invention, the interposer is coupled and locked to the carrier, and the conductive elements are prevented from displacement under pressure. Compared with the prior art, the present invention ensures that the conductive element are in well electrical contact with the interposer.

### BRIEF DESCRIPTION OF DRAWINGS

The invention can be more fully understood by reading the following detailed description of the preferred embodiments, with reference made to the accompanying drawings, wherein:

FIGS. 1A to 1E are cross-sectional diagrams illustrating a method of fabricating a semiconductor package according to the prior art;

FIGS. 2A to 2H are cross-sectional diagrams illustrating a method of fabricating a semiconductor package of a first embodiment according to the prior art, wherein FIG. 2C′ is another embodiment of FIG. 2C; and

FIGS. 3A to 3D are cross-sectional diagrams illustrating a method of fabricating a semiconductor package of a second embodiment according to the prior art, wherein FIG. 3C′ is another embodiment of FIG. 3C.

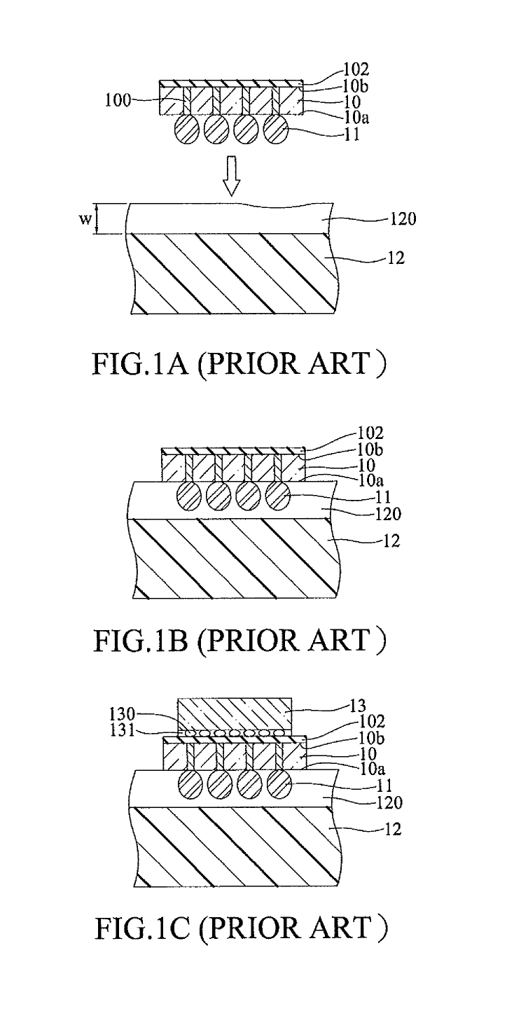

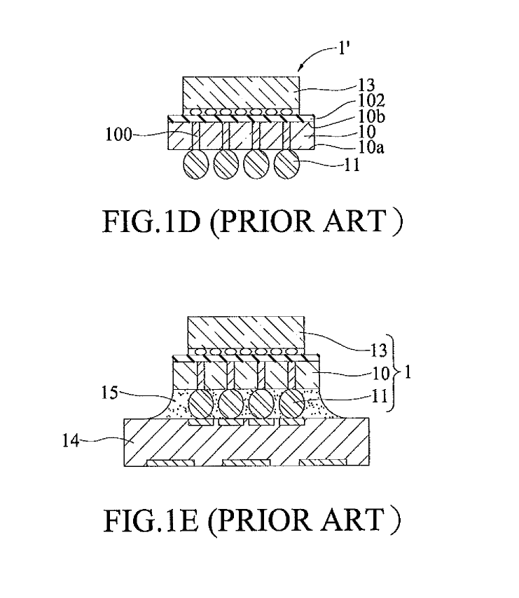

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

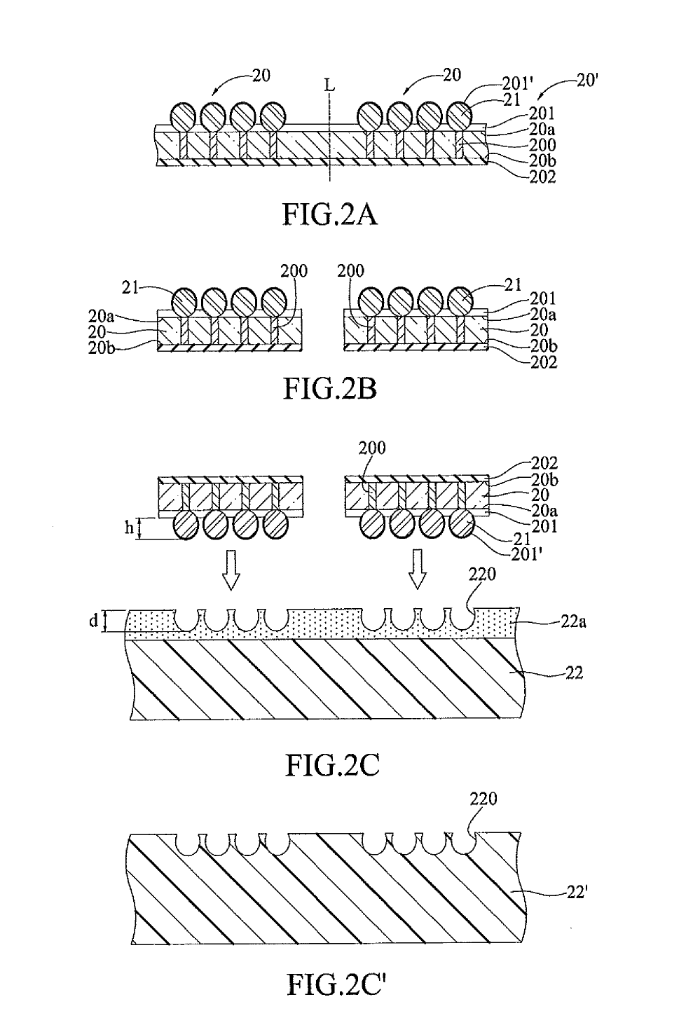

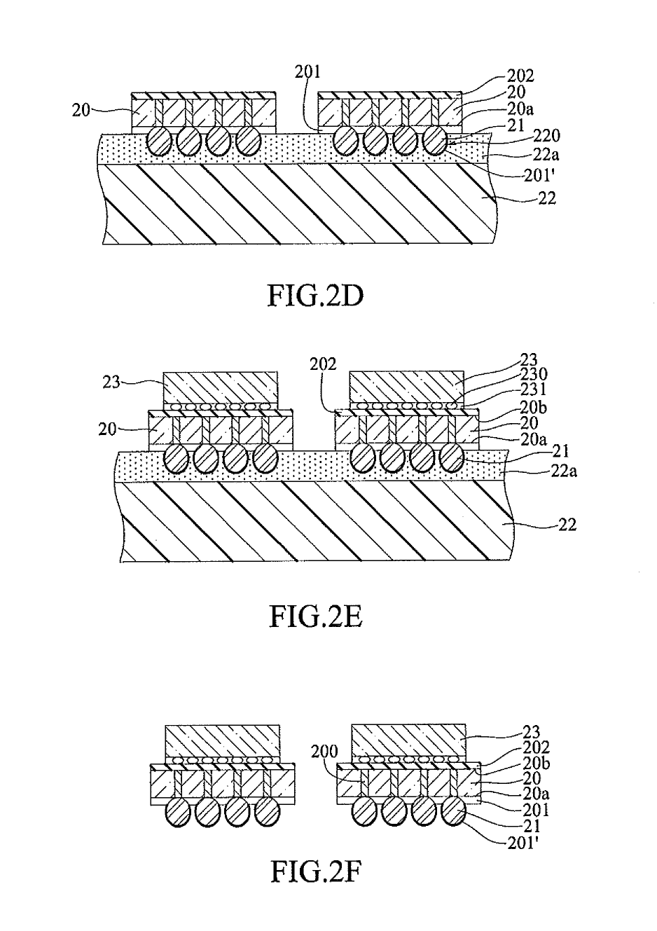

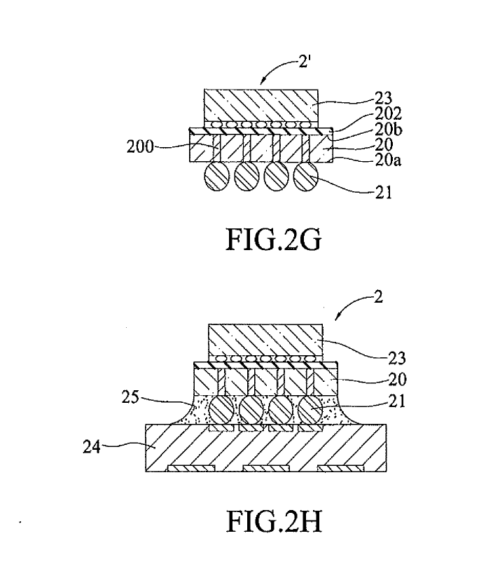

FIGS. 2A to 2H are cross-sectional diagrams illustrating a method of fabricating a semiconductor package 2 of a first embodiment according to the present invention.

As shown in FIG. 2A, an interposer substrate 20′ composed of a plurality of interposers 20 is provided. Each of the interposers 20 has a first surface 20a, a second surface 20b opposite to the first surface 20a, and a plurality of conductive elements 21 disposed on the first surface 20a.

In an embodiment, a plurality of conductive vias 200 are formed in the interposer 20 to communicate the first surface 20a with the second surface 20b, and release films 201 and 201′ are formed on the first surface 20a and the conductive elements 21, respectively. A redistribution layer (RDL) 202 is formed on the second surface 20b of the interposer 20 and electrically connected to the conductive vias 200.

In an embodiment, the interposer 20 is a wafer or a silicon-containing substrate, the conductive vias 200 are through silicon vias (TSV), and the conductive elements 21 are solder balls or the like.

In an embodiment, another redistribution layer (not shown) is formed, on demands, on the first surface 20a of the interposer 20 such that the conductive elements 21 are disposed on pads of the another redistribution layer, and the release films 201 and 201′ cover the another redistribution layer and the conductive elements 21, respectively.

In an embodiment, the redistribution layer 202 and the release films 201 and 201′ are in a variety of patterns.

As shown in FIG. 2B, the complete interposer substrate 20′ is cut along a cutting path L, to obtain a plurality of the interposers 20.

As shown in FIGS. 2C and 2D, a carrier 22 having an insulation layer 22a is provided, and the insulation layer 22a has a plurality of recessed portions 220 formed thereon. The interposer 20 is disposed on the carrier 22 in a manner that the first surface 20a is attached to the insulation layer 22a, and the conductive elements 21 are thus received in the recessed portions 220. As a result, the interposer 20 is coupled and hooked to the carrier 22, and the release films 201 and 201′ are coupled to the carrier 22 and the insulation layer 22a of each of the recessed portions 220. Then, a baking process is performed.

In an embodiment, the carrier 22 is made of a material that is unlikely to be warpaged, such as glass, metal, silicon or the like, the insulation layer 22a is made of colloid or other materials, and the recessed portions 220 are formed by etching the insulation layer 22a. In another embodiment, as shown in FIG. 2C′, no insulation layer is formed, and the recessed portions 220 are formed by etching the carrier 22′ directly. In yet another embodiment, the recessed portion 220 may be formed by other techniques.

In an embodiment, the recessed portions 220 are deep enough for the conductive elements 21 to be coupled and locked thereto. In another embodiment, the depth d of the recessed portions 220 is greater than the height h of a portion of the conductive elements 21 that protrudes from the release film 201. In yet another embodiment, if no release film is formed, the depth d of the recessed portions 220 has to be greater than the height of the conductive elements 21.

As shown in FIG. 2E, a semiconductor element 23 is disposed on the second surface 20b of the interposer 20. In an embodiment, the semiconductor element 23 is coupled and electrically connected to the redistribution layer 202 via a plurality of conductive bumps 230, and an underfill 231 is further formed between the semiconductor element 23 and the redistribution layer 202 to encapsulate the conductive bumps 230.

As shown in FIGS. 2F and 2G, the carrier 22 and the insulation layer 22a are removed. Then, the release films 201 and 201′ are removed, and the semiconductor structure 2′ is thus fabricated.

As shown in FIG. 2H, the semiconductor structure 2′ is disposed via the conductive elements 21 on a packaging substrate 24, an underfill 25 is formed between the semiconductor structure 2 and the packaging substrate 24 to encapsulate the conductive elements 21, and the semiconductor package 2 is thus fabricated.

In the method of fabricating the semiconductor package 2 according to the present invention, the carrier 22 is designed to have the recessed portions 220 that allow the conductive elements 21 to be received therein and the interposer 20 to be coupled and locked to the carrier 22. Therefore, the conductive elements 21 are not required to be pressed into the recessed portions 220, and can be prevented from displacement under pressure. Accordingly, the conductive elements 21 are in well electrical contact with the conductive vias 200.

During the formation of the recessed portions 220, the depths d of the recessed portions 220 are consistent (e.g., by etching out the recessed portions 220 at the same time). Therefore, as the conductive elements 21 are received in and locked to the recessed portions 220, the interposer 20 is not tilted with respect to the carrier 22 (or the insulation layer 22a), and can be disposed on the carrier 22 (or the insulation layer 22a) evenly.

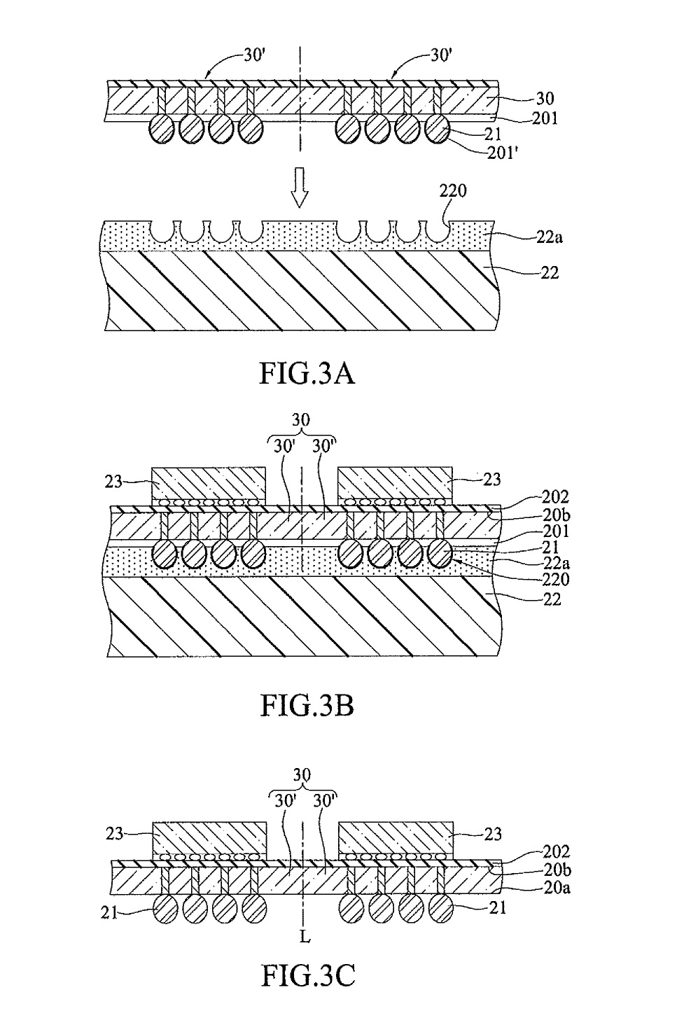

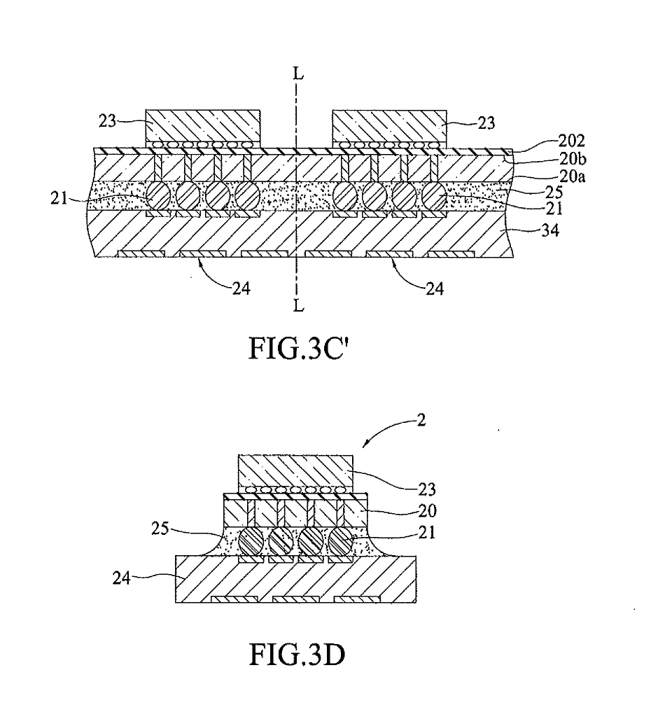

FIGS. 3A to 3D are cross-sectional diagrams illustrating a method of fabricating a semiconductor package 2 of a second embodiment according to the present invention. The second embodiment differs from the first embodiment in the cutting step of the complete interposer substrate 20′.

As shown in FIG. 3A, a large-size interposer substrate 30 (i.e., the complete interposer substrate 20′) having a plurality of interposers 30′ are received in and locked via its conductive elements 21 to the recessed portions 220 of the carrier 22, and the release films 201 and 201′ are coupled to the insulation layer 22a of the carrier 22.

As shown in FIG. 3B, the semiconductor element 23 is coupled to the second surface 20b of the interposer substrate 30 and electrically connected to the redistribution layer 202.

As shown in FIG. 3C, the carrier 22 and the release films 201 and 201′ are removed.

As shown in FIG. 3D, the edges of the interposers 30′ are taken as a cutting path L (as shown in FIG. 3C), and the interposer substrate 30 (the complete interposer substrate 20′) and structures disposed thereon are cut along the cutting path L, to form a plurality of small-size interposers 30′. The small-size interposers 30′ are coupled via the conductive elements 21 to a packaging substrate 24, and an underfill 25 is then formed, such that the semiconductor package 2 is fabricated.

In another cutting flow, as shown in FIG. 3C′, after the carrier 22 and the release films 201 and 201′ are removed, a complete packaging board 34 (that is constituted by a plurality of packaging substrates 24 that correspond to the interposers 30′) is disposed on the conductive elements 21, an underfill 25 is formed, and a cutting process is performed with the edges of the interposers 30′ as a cutting path L, to form a plurality of semiconductor packages 2.

In the method of fabricating a semiconductor package according to the present invention, the carrier is designed to have the recessed portions that allow the conductive elements to be received therein and the interposer to be coupled and locked to the carrier. Therefore, the conductive elements are prevented from displacement under pressure. Accordingly, the conductive elements are in well electrical contact with the conductive vias, and the reliability of an electronic product is increased effectively.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method of fabricating a semiconductor package, comprising:
providing at least an interposer having a first surface, a second opposite to the first surface, and a plurality of conductive elements formed on the first surface;
disposing the interposer on a carrier, the carrier having a plurality of recessed portions for the conductive elements to be received therein such that the interposer is coupled to the carrier;
attaching the semiconductor element to the second surface of the interposer; and
removing the carrier.

2. The method of claim 1, further comprising providing an interposer substrate, and cutting the interposer substrate into a plurality of the interposers, allowing the interposers to be disposed on the carrier.

3. The method of claim 1, further comprising, after removing the carrier, attaching a packaging substrate to the conductive elements.

4. The method of claim 3, further comprising, after removing the carrier, performing a singulation process when an interposer substrate composed of a plurality of the interposers is employed.

5. The method of claim 1, wherein the interposer further has a release film formed on the first surface of the interposer and the conductive elements and attached to the carrier and the recessed portions.

6. The method of claim 5, further comprising, after removing the carrier, removing the release film.

7. The method of claim 1, wherein the interposer has a plurality of conductive vias that communicate the first surface with the second surface.

8. The method of claim 7, wherein the interposer has a redistribution layer formed thereon and electrically connected to the conductive vias, and the semiconductor element is attached and electrically connected to the redistribution layer.

9. The method of claim 7, wherein the interposer is a silicon-containing substrate.

10. The method of claim 1, wherein the recessed portions are formed by etching the carrier.

11. The method of claim 10, wherein the carrier has an insulation layer, and the recessed portions are formed by etching the insulation layer.

12. The method of claim 1, wherein the recessed portions have a depth greater than a height of the conductive elements.

13. The method of claim 1, further comprising, after removing the carrier, performing a singulation process when an interposer substrate composed of a plurality of the interposers is employed.

14. The method of claim 1, wherein the interposer is a silicon-containing substrate.

15. The method of claim 1, wherein the carrier has an insulation layer, and the recessed portions are formed by etching the insulation layer.
